(19) United States
(12) Patent Application Publication
(10) Pub. No.: US 2025/0203933 A1
(43) Pub. Date: Jun. 19, 2025

(54) CONTACT AND PLACEHOLDER CONFIGURATION FOR BACKSIDE POWER DELIVERY DEVICES

(71) Applicant: International Business Machines Corporation, Armonk, NY (US)

(72) Inventors: Huimei Zhou, Albany, NY (US); Ravikumar Ramachandran, Pleasantville, NY (US); Ruilong Xie, Niskayuna, NY (US); Mahender Kumar, Clifton Park, NY (US); Geng Han, Niskayuna, NY (US); Miaomiao Wang, Albany, NY (US)

(21) Appl. No.: 18/539,637

(22) Filed: Dec. 14, 2023

(51) Int. Cl. H01L 29/423; H01L 21/8234; H01L 27/088; H01L 29/06; H01L 29/08; H01L 29/66; H01L 29/775; H01L 29/78; H01L 29/786

(52) U.S. Cl. CPC H10D 30/6735; H10D 30/014; H10D 30/024; H10D 30/43; H10D 30/62; H10D 30/6757; H10D 62/121; H10D 62/151; H10D 64/017; H10D 84/013; H10D 84/0149; H10D 84/0158; H10D 84/038; H10D 84/834

(57) ABSTRACT

A semiconductor device includes a backside source/drain contact and a placeholder disposed between a first gate cut portion and a second gate cut portion, where the backside source/drain contact contacts a frontside inter-layer dielectric layer disposed between a first gate structure associated with the first gate cut portion and a second gate structure associated with the second gate cut portion.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming contact and placeholder configurations for backside power delivery devices. While not limited thereto, the disclosed techniques are well suited for reliability assessments.

In one embodiment, a semiconductor device includes a backside source/drain contact and a placeholder disposed between a first gate cut portion and a second gate cut portion. The backside source/drain contact contacts a frontside inter-layer dielectric layer disposed between a first gate structure associated with the first gate cut portion and a second gate structure associated with the second gate cut portion.

In another embodiment, a semiconductor device includes a first transistor structure comprising a first backside source/drain contact and a first placeholder, where the first backside source/drain contact and the first placeholder are disposed between a first gate cut portion and a second gate cut portion. The semiconductor device includes a second transistor structure comprising a second backside source/drain contact and a second placeholder, where the second backside source/drain contact and the second placeholder are disposed between a third gate cut portion and a fourth gate cut portion. The semiconductor device also includes at least one gate structure that is common to the first transistor structure and the second transistor structure, where the first gate cut portion and a third gate cut portion are within different portions of the at least one gate structure.

In yet another embodiment, a method includes forming a backside inter-layer dielectric layer on a semiconductor structure that surrounds at least a first placeholder and a second placeholder of the semiconductor structure, where the first placeholder is disposed between a first gate cut portion and a second gate cut portion, and the second placeholder is disposed between the first gate cut portion and a third gate cut portion. The method includes removing a portion of the backside inter-layer dielectric layer between the first gate cut portion and the second gate cut portion to expose a portion of the first placeholder, the first placeholder, and a buffer layer formed between the first placeholder and a frontside inter-layer dielectric layer. The method also includes forming a backside source/drain contact in an area resulting from said removing.

These and other features and advantages of embodiments described herein will become more apparent from the accompanying drawings and the following detailed description.

### BRIEF DESCRIPTION OF THE DRAWINGS

FIG. 1 depicts a top view of a semiconductor structure indicating X1, X2, and X3 cross-section locations on which the cross-sectional views of FIGS. 2A-7C are based, according to an illustrative embodiment.

FIG. 2A depicts a first cross-sectional view of the semiconductor structure at an intermediate stage in the fabrication process corresponding to line X1 in FIG. 1, according to an illustrative embodiment.

FIG. 2B depicts a second cross-sectional view of the semiconductor structure at an intermediate stage in the fabrication process corresponding to line X2 in FIG. 1, according to an illustrative embodiment.

FIG. 2C depicts a third cross-sectional view of the semiconductor structure at an intermediate stage in the fabrication process corresponding to line X3 in FIG. 1, according to an illustrative embodiment.

FIG. 3A depicts a first cross-sectional view corresponding to the line X1 in FIG. 1 following substrate and etch stop removal, according to an illustrative embodiment.

FIG. 3B depicts a second cross-sectional view corresponding to the line X2 in FIG. 1 following substrate and etch stop removal, according to an illustrative embodiment.

FIG. 3C a second cross-sectional view corresponding to the line X3 in FIG. 1 following substrate and etch stop removal, according to an illustrative embodiment.

FIG. 4A depicts a first cross-sectional view corresponding to the line X1 in FIG. 1 following backside interlayer dielectric (ILD) layer formation, according to an illustrative embodiment.

FIG. 4B depicts a second cross-sectional view corresponding to the line X2 in FIG. 1 following backside ILD layer formation, according to an illustrative embodiment.

FIG. 4C a second cross-sectional view corresponding to the line X3 in FIG. 1 following backside ILD layer formation, according to an illustrative embodiment.

FIG. 5A depicts a first cross-sectional view corresponding to the line X1 in FIG. 1 following backside ILD layer patterning for backside contacts, according to an illustrative embodiment.

FIG. 5B depicts a second cross-sectional view corresponding to the line X2 in FIG. 15 following backside ILD layer patterning for backside contacts, according to an illustrative embodiment.

FIG. 5C depicts a third cross-sectional view corresponding to the line X3 in FIG. 15 following backside ILD layer patterning for backside contacts, according to an illustrative embodiment.

FIG. 6A depicts a first cross-sectional view corresponding to the line X1 in FIG. 1 following placeholder layer removal, according to an illustrative embodiment.

FIG. 6B depicts a second cross-sectional view corresponding to the line X2 in FIG. 1 following placeholder layer removal, according to an illustrative embodiment.

FIG. 6C a second cross-sectional view corresponding to the line X3 in FIG. 1 following placeholder layer removal, according to an illustrative embodiment.

FIG. 7A depicts a first cross-sectional view corresponding to the line X1 in FIG. 1 following backside contact formation, according to an illustrative embodiment.

FIG. 7B depicts a second cross-sectional view corresponding to the line X2 in FIG. 1 following substrate and etch stop removal, according to an illustrative embodiment.

FIG. 7C a second cross-sectional view corresponding to the line X3 in FIG. 1 following substrate and etch stop removal, according to an illustrative embodiment.

### DETAILED DESCRIPTION

Illustrative embodiments of the invention may be described herein in the context of illustrative methods for forming contact and placeholder configurations for backside power delivery, along with illustrative apparatus, systems and devices formed using such methods. However, it is to be understood that embodiments of the invention are not limited to the illustrative methods, apparatus, systems, and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A FET is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in fin field-effect transistors (FinFET). Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 20 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including using fin-shaped channels in FinFET devices, using stacked nanosheet channels formed over a semiconductor substrate, and using next-generation stacked FET devices.

Although embodiments described herein are discussed in connection with nanosheet stacks, the embodiments are not necessarily limited thereto, and may similarly apply to nanowire stacks.

The concept of buried power rail (BPR) refers to power rails that are buried below the back end of line (BEOL) metal stack, usually in-level with the transistor fins themselves. Back side power distribution networks (BSPDN), or grids, enable scaling beyond 5 nm with the back side being below the transistor substrate. The BPR technology enables the freeing up of resources for the dense logic connections often limiting modem processor performance. Further scaling of a standard logic cell is enabled by removing the overhead in the area occupied by the power rails. Finally, thicker low-resistance power rails are allowed, which enable lower voltage (IR) drops.

Evaluating the reliability between a gate and a placeholder for BSPDNs is often challenging. Conventional designs are generally limited to evaluating the reliability of a backside contact to a gate, as a metal layer replaces the placeholder once the placeholder is opened after patterning the backside contact. At least some embodiments described herein can provide semiconductor devices that enable evaluation of a gate to a back side placeholder. More particularly, the configuration of a backside source/drain contact and a placeholder in a semiconductor device as described herein advantageously allows the gate structure to placeholder reliability to be assessed for backside power delivery architectures.

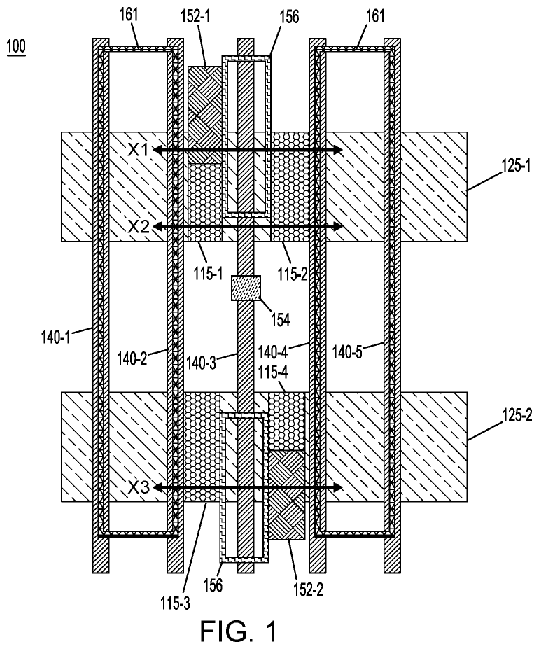

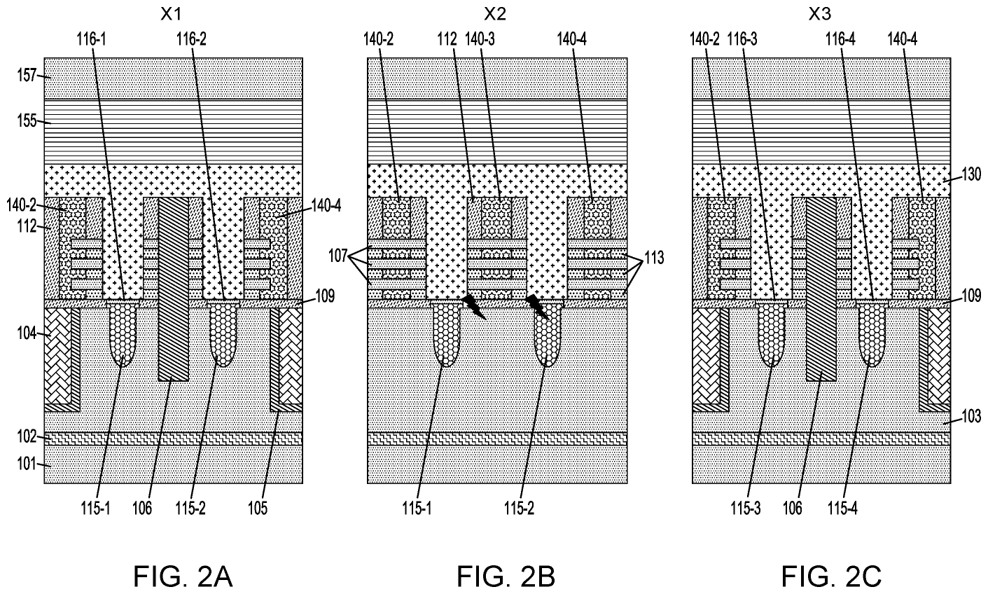

FIG. 1 depicts atop view of a semiconductor structure 100 with lines X1, X2, and X3 on which the cross-sectional views of FIGS. 2A-7C are based. More specifically, FIG. 1 shows active areas 125-1 and 125-2 (collectively active areas 125) and gate structures 140-1 to 140-5 (collectively gate structures 140). The active areas 125 typically correspond to source/drain regions of respective transistors. The semiconductor structure 100 shown in FIG. 1 includes backside source/drain contacts (BSCAs) 152-1 and 152-2 (collectively BSCAs 152) associated with the respective active areas 125, and a frontside gate contact 154 associated with gate structure 140-3. In this example, the semiconductor structure 100 includes FS regions 156 and FC regions 161.

Generally, the FS regions 156 and FC regions 161 are formed using different “fin cut” etching processes that remove unwanted fins or portions thereof. An FC cut process can be performed to remove portions of fins associated with the FC regions 161. In some embodiments, the FC regions 161 resulting from an FC cut can be used to form a double diffusion break structure, as explained in more detail elsewhere herein. An FS region 156 can be formed using a different type of fin cut (referred to as an “FS cut”) along a portion of a single gate structure. For example, the FS regions 156 in FIG. 1 are formed along the gate structure 140-3 in a portion of each of active areas 125, as shown. In some embodiments, the FS cut can be used to form a single diffusion break structure, as explained in more detail elsewhere herein.

It is also noted that the lightning-like shapes in FIGS. 2B-7B indicate potential failure points, between gates and backside placeholders. As noted above, these points are generally difficult to evaluate in conventional designs.

Referring to FIG. 1 and to the cross-sectional views in FIGS. 2A, 2B and 2C, which respectively correspond to the lines X1, X2, and X3 in FIG. 1, a semiconductor structure 100 includes a stacked structure of channel layers 107 and gate structures 140. In an illustrative embodiment, the channel layers 107 comprise silicon. In an illustrative embodiment, the gate structures 140 are formed after a replacement metal gate (RMG) process in which sacrificial layers are removed and replaced with the gate structures 140. It is noted that the cross-sectional views depicted in FIGS. 2A-7C show gate structures 140-2 to 140-4.

In illustrative embodiments, each gate structure 140 includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the gate structures 140 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

Gate spacers 112 are formed on sides of the gate structures 140. The spacer material can comprise for example, one or more dielectrics, including, but not necessarily limited to, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN), silicon oxide (SiOₓ) (where x is for example, 2, 1.99 or 2.01) and combinations thereof. The gate spacers 112 can be formed by any suitable techniques such as deposition followed by directional etching. Deposition may include but is not limited to, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD). Directional etching may include but is not limited to, reactive ion etching (RIE).

Inner spacers 113 are disposed on opposite sides of lower gate structures 140 under and/or over end portions of the channel layers 107. The material of the inner spacers 113 can comprise, but is not necessarily limited to, a nitride, such as, SiN, SiON, SiCN, BN, SiBN, SiBCN or SiOCN. In an illustrative embodiment, the gate spacers 112 are formed from the same or similar material to that of the inner spacers 113. Like the gate spacers 112, the inner spacers 113 can be formed by any suitable techniques such as deposition followed by directional etching.

The lowermost gate structures 140 of the nanosheet stacks are formed on bottom dielectric isolation (BDI) layers 109, which may comprise, for example, silicon oxide SiOₓ, silicon oxycarbide (SiOC), SiN, SiON, SiCN, BN, SiBCN, SiOCN or some other dielectric. The BDI layers 109 are under bottom surfaces of the lowermost gate structures 140.

First and second semiconductor substrates 101 and 103 comprise semiconductor material including, but not limited to, silicon (Si), III-V, II-V compound semiconductor materials or other like semiconductor materials. In addition, multiple layers of the semiconductor materials can be used as the semiconductor material of the first and second semiconductor substrates 101 and 103. An etch stop layer 102 is formed on the first semiconductor substrate 101, and may comprise, for example, SiOₓ, or silicon germanium (SiGe). In illustrative embodiments, the etch stop layer 102 comprises a germanium concentration of about 30% (e.g., SiGe30), but the embodiments are not necessarily limited to SiGe30 for the etch stop layer 102. The second semiconductor substrate 103 comprising, for example, the same semiconductor material as the first semiconductor substrate 101, or other like semiconductor material, is formed on the etch stop layer 102.

Isolation regions comprising a fill portion 104 and a liner portion 105 are formed in the second semiconductor substrate 103 beneath nanosheet stacks comprising channel layers 107 and gate structures 140. The isolation regions in FIG. 1 correspond to the FC regions 161, for example. In illustrative embodiments, the fill portion 104 comprises an oxide (e.g., SiOₓ) and the liner portion 105 comprises a nitride (e.g., SiN, SiON, SiCN, BN, SiBCN, SiOCN).

Placeholder semiconductor layers 115-1, 115-2, 115-3, and 115-4 (collectively “placeholder semiconductor layers 115”) and buffer semiconductor layers 116-1, 116-2, 116-3, and 116-4 (collectively “buffer semiconductor layers 116”) are formed between the nanosheet stacks. It is noted that source/drain regions are typically formed above the placeholder semiconductor layers 115 and buffer semiconductor layers 116. In some embodiments, an etching process such as, for example, RIE, is performed on exposed portions of the BDI layer 109 and underlying portions of the second semiconductor substrate 103 between the nanosheet stacks to form openings (e.g., trenches) in the second semiconductor substrate 103. The openings are formed by etching through parts of the BDI layer 109 and parts of the second semiconductor substrate 103 and comprise a U-shape.

In illustrative embodiments, the placeholder semiconductor layers 115 comprise, for example, SiGe, III-V semiconductor material or other semiconductor material, and the buffer semiconductor layers 116 comprise, for example, silicon or other semiconductor material. The placeholder semiconductor layers 115 and buffer semiconductor layers 116 are epitaxially grown. The buffer semiconductor layers 116 are epitaxially grown from the exposed surfaces of their corresponding placeholder semiconductor layers 115. In more detail, the buffer semiconductor layers 116 are grown from top surfaces of the placeholder semiconductor layers 115.

As noted above, an FS cut process (which can include an etching process, such as RIE) is performed on portions of the channel structure 140-3 along the FS regions 156, as well as the corresponding portions of the BDI layer 109 and portions of the second semiconductor substrate 103 beneath the channel structure 140-3 to form openings (e.g., trenches) in the second semiconductor substrate 103. In illustrative embodiments, the opening can be filled to form respective isolation regions 106 (corresponding to the FS regions 156). The isolation regions 106 can comprise, e.g., a nitride (e.g., SiN, SiON, SiCN, BN, SiBCN, SiOCN).

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low-pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

It is noted that in this example, the widths of the channel layers 107 corresponding to gate structures 140-2 and 140-4 along lines X1 and X3 are narrower than the widths along X2, gate spacers 112 corresponding to the left side of channel structure 140-2 and the right side of channel structure 140-4 remain intact, and are substantially the same height as the channel structures 140-1 and 140-2. This arrangement is a result of the FC cut process, for example.

An inter-layer dielectric (ILD) layer 130 fills in portions between the nanosheet stacks. The ILD layer 130 can be deposited using deposition techniques such as, for example, CVD, PECVD, RFCVD, PVD, ALD, MBD, PLD, and/or LSMCD, followed by a planarization process, such as, CMP. The ILD layer 130 may comprise, for example, SiOₓ, SiOC, SiOCN or some other dielectric material.

As used herein, “frontside or “first side” refers to a side on top of the first and second semiconductor substrates 101 and 103 and/or in front of, on top of or in an upward direction from the stacked nanosheet/gate and channel layers of the transistors in the orientation shown in the cross-sectional figures. As used herein, “backside” or “second side” refers to a side below the first and/or second semiconductor substrates 101 and 103 and/or behind, below or in a downward direction from the stacked nanosheet/gate and channel layers of the transistors in the orientation shown in the cross-sectional figures (e.g., opposite the “frontside”).

In some embodiments, middle-of-line (MOL) contacts and frontside BEOL interconnects 155 are formed, and a carrier wafer 157 is bonded to the frontside BEOL interconnects 155. For example, the formation of the MOL contacts can include forming the frontside gate contact 154 through the ILD layer 130 such that it lands on and contacts the gate structure 140-3 (may also be referred to as a gate region). The gate contact 154 may include a silicide layer such as titanium (Ti), nickel (Ni), nickel platinum (NiPt), etc., and a metal adhesion layer (e.g., such as TiN) and a low resistance metal such as ruthenium (Ru), tungsten (W), cobalt (Co) or another suitable material. The frontside BEOL interconnects 155 can include various BEOL interconnect structures. The carrier wafer 157 may be formed of materials similar to that of the substrate 101 and may be formed over the frontside BEOL interconnects 155 using a wafer bonding process, such as dielectric-to-dielectric bonding.

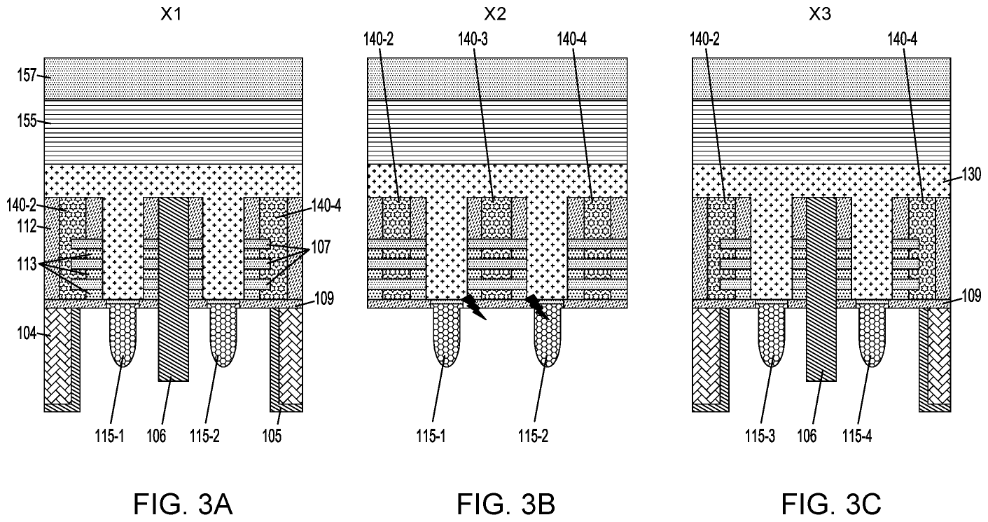

FIGS. 3A to 3C depict cross-sectional views of the semiconductor structure 100 following substrate and etch stop removal, according to an illustrative embodiment, using the carrier wafer 157, the semiconductor structure 100 may be “flipped” (e.g., rotated 180 degrees) so that the structure is inverted. The first semiconductor substrate 101 can be removed from the backside of the semiconductor structure 100. The removal process, which comprises etching of the first semiconductor substrate 101, stops at the etch stop layer 102. The etch stop layer 102 can then be removed, and the second semiconductor substrate 103 (e.g., silicon layer) can be selectively removed with respect to the isolation regions comprising the fill and liner portions 104, 105, and 106, followed by removal of the second semiconductor substrate 103 to expose the placeholder semiconductor layers 115. Etching processes for removal of the etch stop layer 102 include, for example, IBE by Ar/CHF3 based chemistry. Etchants for removing the second semiconductor substrate 103 include, for example, potassium hydroxide (KOH) and tetramethylammonium hydroxide (TMAH).

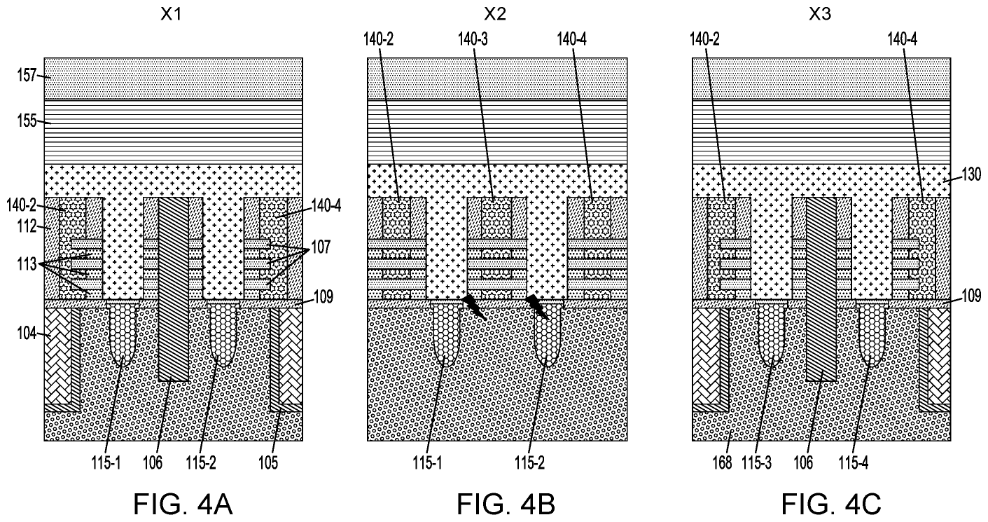

FIGS. 4A to 4C depict cross-sectional views of the semiconductor structure 100 following backside ILD layer formation, according to an illustrative embodiment. A backside ILD layer 168 is deposited to fill in areas formerly occupied by the second semiconductor substrate 103. The backside ILD layer 168 may be formed of similar materials as the ILD layer 130, for example. In some embodiments, the material of the backside ILD layer 168 may initially be overfilled, followed by a planarization process (e.g., using CMP) so that the backside ILD layer 168 surrounds the fill and liner portions 104, 105, and 106, as well as the placeholder semiconductor layers 115, as shown.

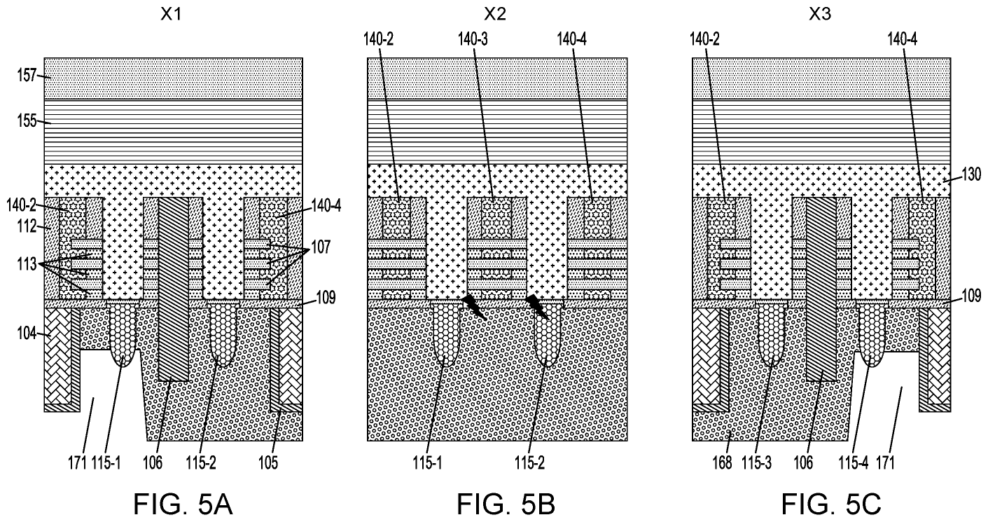

FIGS. 5A to 5C depict cross-sectional views of the semiconductor structure 100 following backside ILD layer patterning for BSCAs 152-1 and 152-2, according to an illustrative embodiment. The backside ILD layer patterning can include removing portions of the backside ILD layer 168 to expose the placeholder semiconductor layers 115. In some embodiments, a mask is applied to the ILD layer 168, and the exposed portions of the backside ILD layer 168 are removed using, for example, a dry etching process using a RIE or IBE process, a wet chemical etching process or a combination of these etching processes. A dry etch may be performed using a plasma. Such wet or dry etch processes can include, for example, IBE by Ar/CHF3 based chemistry. The etching process creates openings 171 in the backside ILD layer 168.

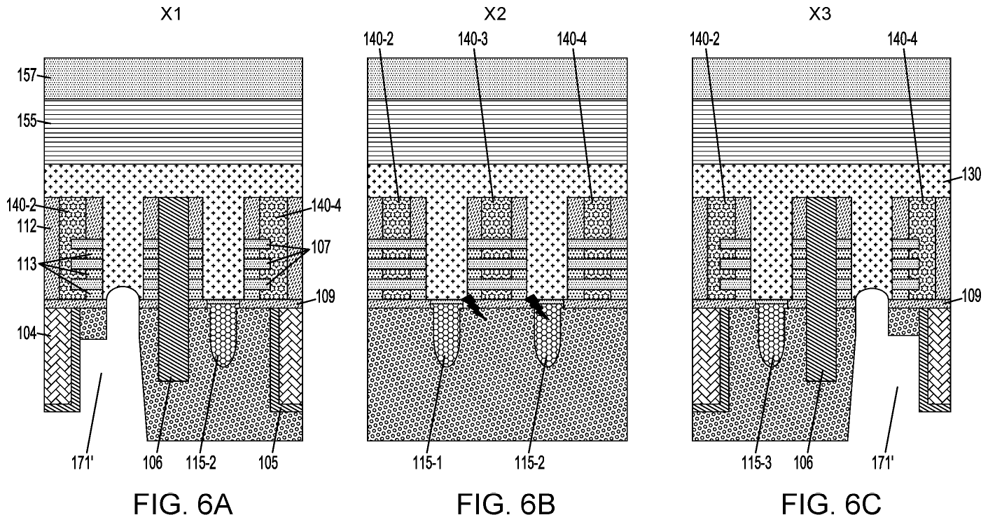

FIGS. 6A to 6C depict cross-sectional views of the semiconductor structure 100 following placeholder layer removal, according to an illustrative embodiment. In this example, placeholder semiconductor layers 115-1 and 115-4 and corresponding buffer semiconductor layers 116-1 and 116-4 are selectively removed to expose backside portions of the ILD layer 130, thereby creating openings 171′. Optionally, the exposed backside portions of the ILD layer 130 are gouged to create an arc-like shape, as shown in FIGS. 6A and 6C. The placeholder semiconductor layers 115-1 and 115-4 and corresponding buffer semiconductor layers 116-1 and 116-4 are removed using, for example, a selective dry or wet etch process.

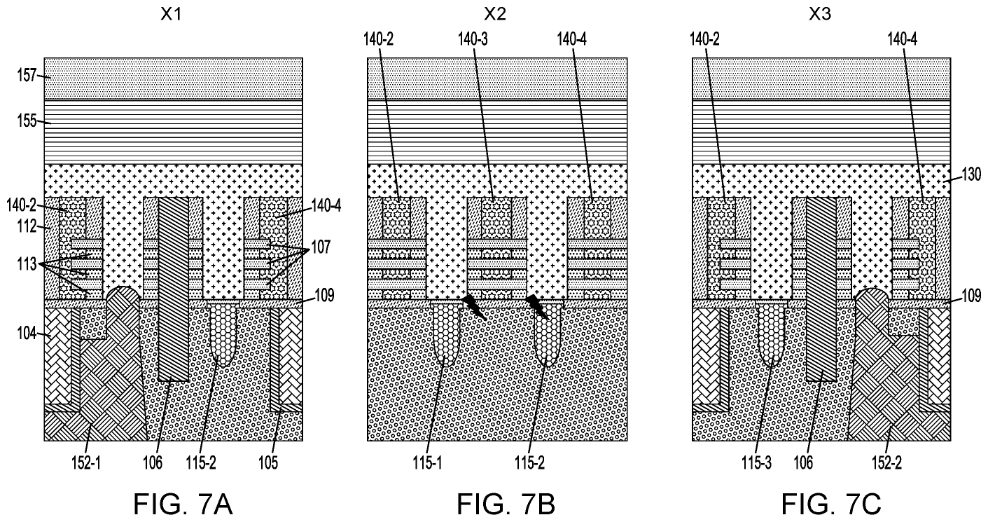

FIGS. 7A to 7C depict cross-sectional views of the semiconductor structure 100 following backside contact formation, according to an illustrative embodiment. The BSCAs 152-1 and 152-2 are formed in the backside ILD layer 168 in the openings 171′. For example, metal layers can be deposited in the openings 171′ to form the BSCAs 152-1 and 152-2. The metal layers can comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as CMP to remove excess portions of the metal layers from on top of the backside ILD layer 168.

In at least some embodiments, the BSCAs 152 can connect to a BSPDN layer (also referred to herein as backside interconnects). For example, additional ILD material can be deposited to form an additional backside ILD layer on the backside ILD layer 168, and a backside power rail (e.g., conductive wires) can be formed in portions of the additional backside ILD layer. Openings can be formed through portions of the additional backside ILD layer, where at least one opening exposes a portion of the BSCAs 152 on which the backside power rail is formed. The backside power rail can then be formed in the additional backside ILD layer by forming one or more trenches in the additional backside ILD layer and filling the one or more trenches with conductive material.

It is noted that the example semiconductor structure 100 allows gate to placeholder evaluation. The reliability corresponding to the lightning-like shape associated with placeholder 115-1 in FIG. 7B can be determined by applying a voltage (V) to the gate structure 140-3 and applying no voltage (0) to the BSCA 152-1, for example.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

Gate to placeholder evaluation of BSPDNs architectures is often challenging as a metal layer replaces the placeholder once the placeholder is opened after patterning the backside contact. This limits the ability to evaluate the reliability of the backside contact to the gate. Without in any way limiting the scope, interpretation, or application of the claims appearing below, a technical effect of one or more of the example embodiments disclosed herein is providing a semiconductor structure that allows gate to placeholder evaluation for BSPDN architecture.

In some embodiments, a semiconductor device includes a backside source/drain contact and a placeholder disposed between a first gate cut portion and a second gate cut portion. The backside source/drain contact contacts a frontside inter-layer dielectric layer disposed between a first gate structure associated with the first gate cut portion and a second gate structure associated with the second gate cut portion.

The first gate cut portion is formed within a portion of the first gate structure. The first gate cut portion may include an insulating material. The first gate structure may include a frontside gate contact. The placeholder may be disposed beneath the frontside inter-layer dielectric layer between the first gate structure and a second gate structure associated with the second gate cut portion. The second gate cut portion may be formed using a fin cut process. The backside source/drain contact may be connected to a backside power delivery network. The semiconductor device may include a transistor structure corresponding to a fin field-effect transistor, where the transistor structure comprises the backside source/drain contact and the placeholder.

It is to be appreciated that the term “transistor structure” in this context refers to a transistor-like structure that can be used for testing or evaluation purposes. In this regard, at least some transistor structures described herein can include a backside source/drain contact that does not contact a source/drain region (as is typically the case for transistors such as FETs). Rather, the backside source/drain contact contacts the frontside inter-layer dielectric layer.

In some embodiments, a semiconductor device comprises a first transistor structure comprising a first backside source/drain contact and a first placeholder, where the first backside source/drain contact and the first placeholder are disposed between a first gate cut portion and a second gate cut portion. The semiconductor device includes a second transistor structure comprising a second backside source/drain contact and a second placeholder, where the second backside source/drain contact and the second placeholder are disposed between a third gate cut portion and a fourth gate cut portion. The semiconductor device also includes at least one gate structure that is common to the first transistor structure and the second transistor structure, where the first gate cut portion and the third gate cut portion are within different portions of the at least one gate structure.

At least one of the first transistor structure and second transistor structure may correspond to a fin field-effect transistor. The first gate cut portion and the third gate cut portion may include single diffusion break structures. The second gate cut portion and the fourth gate cut portion may include double diffusion break structures. The at least one gate structure may include a frontside gate contact. At least one of the first backside source/drain contact and the second backside source/drain contact may be connected to a backside power delivery network. The first backside source/drain contact may contact a frontside inter-layer dielectric layer of the first transistor structure that is disposed between a first gate structure associated with the first gate cut portion and a second gate structure associated with the second gate cut portion.

In some embodiments, a method includes forming a backside inter-layer dielectric layer on a semiconductor structure that surrounds at least a first placeholder and a second placeholder of the semiconductor structure, wherein the first placeholder is disposed between a first gate cut portion and a second gate cut portion, and the second placeholder is disposed between the first gate cut portion and a third gate cut portion. The method includes removing a portion of the backside inter-layer dielectric layer between the first gate cut portion and the second gate cut portion to expose a portion of the first placeholder, the first placeholder, and a buffer layer formed between the first placeholder and a frontside inter-layer dielectric layer. The method also includes forming a backside source/drain contact in an area resulting from the removing.

The removing the portion of the backside inter-layer dielectric layer between the first gate cut portion and the second gate cut portion may include forming a mask layer to cover at least one other portion of the backside inter-layer dielectric layer between the first gate cut portion and the third gate cut portion, performing a first etching process that etches through the first placeholder, and performing a second etching process that etches through the buffer layer. The backside source/drain contact may include at least one metal layer. The first gate cut portion may include a single diffusion break structure. The second gate cut portion may include a double diffusion break structure.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a backside source/drain contact and a placeholder disposed between a first gate cut portion and a second gate cut portion;
wherein the backside source/drain contact contacts a frontside inter-layer dielectric layer disposed between a first gate structure associated with the first gate cut portion and a second gate structure associated with the second gate cut portion.

2. The semiconductor device of claim 1, wherein the first gate cut portion is formed within a portion of the first gate structure.

3. The semiconductor device of claim 1, wherein the first gate cut portion comprises an insulating material.

4. The semiconductor device of claim 1, wherein the first gate structure comprises a frontside gate contact.

5. The semiconductor device of claim 1, wherein the placeholder is disposed beneath the frontside inter-layer dielectric layer between the first gate structure and a second gate structure associated with the second gate cut portion.

6. The semiconductor device of claim 1, wherein the second gate cut portion is formed using a fin cut process.

7. The semiconductor device of claim 1, wherein the backside source/drain contact is connected to a backside power delivery network.

8. The semiconductor device of claim 1, comprising a transistor structure corresponding to a fin field-effect transistor, wherein the transistor structure comprises the backside source/drain contact and the placeholder.

9. A semiconductor device comprising:
a first transistor structure comprising a first backside source/drain contact and a first placeholder, wherein the first backside source/drain contact and the first placeholder are disposed between a first gate cut portion and a second gate cut portion;
a second transistor structure comprising a second backside source/drain contact and a second placeholder, wherein the second backside source/drain contact and the second placeholder are disposed between a third gate cut portion and a fourth gate cut portion; and
at least one gate structure that is common to the first transistor structure and the second transistor structure;
wherein the first gate cut portion and the third gate cut portion are within different portions of the at least one gate structure.

10. The semiconductor device of claim 9, wherein at least one of the first transistor structure and second transistor structure corresponds to a fin field-effect transistor.

11. The semiconductor device of claim 9, wherein the first gate cut portion and the third gate cut portion comprise single diffusion break structures.

12. The semiconductor device of claim 9, wherein the second gate cut portion and the fourth gate cut portion comprise double diffusion break structures.

13. The semiconductor device of claim 9, wherein the at least one gate structure comprises a frontside gate contact.

14. The semiconductor device of claim 9, wherein at least one of the first backside source/drain contact and the second backside source/drain contact is connected to a backside power delivery network.

15. The semiconductor device of claim 9, wherein the first backside source/drain contact contacts a frontside inter-layer dielectric layer of the first transistor structure that is disposed between a first gate structure associated with the first gate cut portion and a second gate structure associated with the second gate cut portion.

16. A method comprising:
forming a backside inter-layer dielectric layer on a semiconductor structure that surrounds at least a first placeholder and a second placeholder of the semiconductor structure, wherein the first placeholder is disposed between a first gate cut portion and a second gate cut portion, and the second placeholder is disposed between the first gate cut portion and a third gate cut portion;
removing a portion of the backside inter-layer dielectric layer between the first gate cut portion and the second gate cut portion to expose a portion of the first placeholder, the first placeholder, and a buffer layer formed between the first placeholder and a frontside inter-layer dielectric layer; and
forming a backside source/drain contact in an area resulting from said removing.

17. The method of claim 16, wherein removing the portion of the backside inter-layer dielectric layer between the first gate cut portion and the second gate cut portion comprises:
forming a mask layer to cover at least one other portion of the backside inter-layer dielectric layer between the first gate cut portion and the third gate cut portion;
performing a first etching process that etches through the first placeholder; and
performing a second etching process that etches through the buffer layer.

18. The method of claim 16, wherein the backside source/drain contact comprises at least one metal layer.

19. The method of claim 16, wherein the first gate cut portion comprises a single diffusion break structure.

20. The method of claim 16, wherein the second gate cut portion comprises a double diffusion break structure.
